(19) United States
(12) Patent Application Publication
(10) Pub. No.: US 2023/0178684 A1
(43) Pub. Date: Jun. 8, 2023

(54) LIGHT-EMITTING DEVICE

(71) Applicant: Xiamen Sanan Optoelectronics Technology Co., Ltd., Fujian (CN)

(72) Inventors: Bin JIANG, Fujian (CN); Yashu ZANG, Fujian Province (CN); Chung-Ying CHANG, Fujian Province (CN); Kang-Wei PENG, Fujian (CN); Sihe CHEN, Fujian Province (CN); Siyi LONG, Fujian Province (CN); Mingchun TSENG, Fujian (CN); Gong CHEN, Fujian (CN); Weichun TSENG, Fujian (CN)

(21) Appl. No.: 17/984,956

(22) Filed: Nov. 10, 2022

(30) Foreign Application Priority Data
Dec. 8, 2021 (CN) 202111491934.6

(51) Int. Cl. H01L 33/10; H01L 33/32; H01L 33/38; H01L 33/62

(52) U.S. Cl. CPC H01L 33/10; H01L 33/32; H01L 33/382; H01L 33/62

(57) ABSTRACT

A light-emitting device includes a substrate, a first type semiconductor layer, a protrusion, and a first reflection structure. The first type semiconductor layer is disposed on a surface of the substrate, and has a surface that has first and second conductive regions. The first type semiconductor layer is made of AlₓGa₁₋ₓN, and x ranges from 0 to 1. A protrusion includes an active layer and a second type semiconductor layer that are sequentially disposed on the first conductive region of the surface of the first type semiconductor layer in such order. A first reflection structure is disposed in the protrusion, and penetrates through the second type semiconductor layer, the active layer of the protrusion and into the first type semiconductor layer. The light-emitting device emits light that has an emission wavelength ranging from 200 nm to 320 nm.

### CROSS-REFERENCE TO RELATED APPLICATION

This application claims priority to Chinese Invention Patent Application No. 202111491934.6, filed on Dec. 8, 2021, which is incorporated herein by reference in its entirety.

### FIELD

The disclosure relates to a semiconductor device, and more particularly to a light-emitting device.

### BACKGROUND

An ultraviolet light-emitting diode is a light-emitting diode that emits light that has an emission wavelength ranging from 100 nm to 365 nm. The ultraviolet light-emitting diode may be applied in various fields, such as ultraviolet curing, sterilization, medicine, biochemical detection, and confidential communication. Compared with conventional ultraviolet light sources, such as mercury, a deep ultraviolet light-emitting diode made of aluminum gallium nitride (AlGaN) is robust, energy-saving, long-lasting and mercury-free, and is gradually replacing the conventional ultraviolet light sources.

Currently, an epitaxial layer of the deep ultraviolet light-emitting diode is mainly made of aluminum indium gallium nitride (AlInGaN). Because an aluminum concentration in AlInGaN for forming the epitaxial layer of the deep ultraviolet light-emitting diode is higher, light laterally propagates in the epitaxial layer in the transverse magnetic (TM) field polarization mode. However, when laterally propagating, light may be absorbed by the epitaxial layer, thereby being not efficiently emitted out of the epitaxial layer and affecting the luminous efficiency of the deep ultraviolet light-emitting diode.

### SUMMARY

Therefore, an object of the disclosure is to provide a light-emitting device that can alleviate at least one of the drawbacks of the prior art.

According to the disclosure, the light-emitting device includes a substrate, a first type semiconductor layer, a protrusion, and a first reflection structure.

The first type semiconductor layer is disposed on a surface of the substrate, and has a surface that has a first conductive region and a second conductive region. The first type semiconductor layer is made of AlₓGa₁₋ₓN, and x ranges from 0 to 1.

A protrusion includes an active layer and a second type semiconductor layer that are sequentially disposed on the first conductive region of the surface of the first type semiconductor layer in such order.

A first reflection structure is disposed in the protrusion, and penetrates through the second type semiconductor layer, the active layer of the protrusion and into the first type semiconductor layer.

The light-emitting device emits light that has an emission wavelength ranging from 200 nm to 320 nm.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1A is a schematic top view illustrating a first embodiment of a light-emitting device according to the disclosure.

FIG. 1B is a cross-sectional view taken along line A-A of FIG. 1A.

FIG. 2 is a variation of the first embodiment.

FIG. 3 is a schematic view illustrating a second embodiment of the light-emitting device according to the disclosure.

FIG. 4 is a schematic view illustrating a third embodiment of the light-emitting device according to the disclosure.

FIG. 5 is a variation of the third embodiment.

FIG. 6 is another variation of the third embodiment.

FIG. 7 is a flow chart illustrating consecutive steps of a method for making the first embodiment of the light-emitting device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

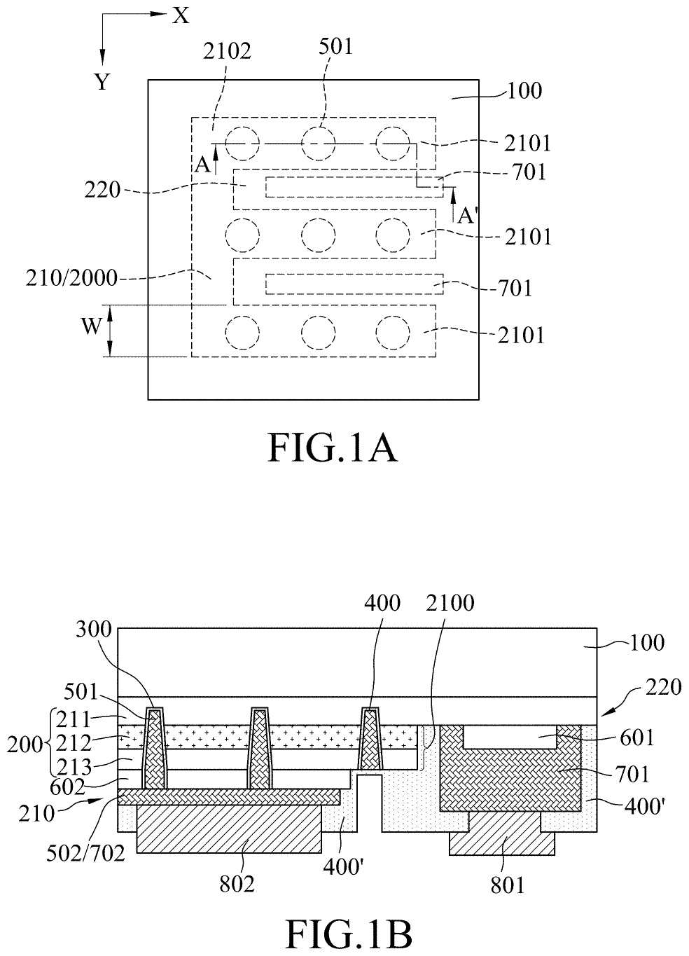

Referring to FIGS. 1A and 1B, a first embodiment of a light-emitting device according to the present disclosure includes a substrate 100, a first type semiconductor layer 211, a protrusion 2100, and a first reflection structure 501. The first type semiconductor layer 211 is disposed on a surface of the substrate 100, and has a surface that has a first conductive region 210 and a second conductive region 220. The protrusion 2100 includes an active layer 212 and a second type semiconductor layer 213 that are sequentially disposed on the first conductive region 210 of the surface of the first type semiconductor layer 211 in such order. The first reflection structure 501 is disposed in the protrusion 2100, and penetrates through the second type semiconductor layer 213, the active layer 212 of the protrusion 2100 and into the first type semiconductor layer 211. The light-emitting device emits light that has an emission wavelength ranging from 200 nm to 320 nm.

In certain embodiments, the substrate 100 may be one of a sapphire substrate, a silicon (Si) substrate, a silicon carbide (SiC) substrate, and a gallium nitride (GaN) substrate. In this embodiment, the substrate 100 is a sapphire substrate.

The protrusion 2100 and the first type semiconductor layer 211 corporately form an epitaxial layer 200. In this embodiment, the first type semiconductor layer 211 is an N-type semiconductor layer, and is made of AlₓGa₁₋ₓN, wherein x ranges from 0 to 1. In alternative embodiments, x may range from 0.5 to 0.8. The second type semiconductor layer 213 is made of P-type GaN. The active layer 212 includes at least one of AlGaN quantum well layer and at least one of AlGaN quantum barrier layer. In certain embodiments, the active layer 212 has a periodic and repeated structure that includes a plurality of the AlGaN quantum well layers and a plurality of the AlGaN quantum barrier layers that are alternating stacked. The epitaxial layer 200 may emit an ultraviolet light that has an emission wavelength that is smaller than 285 nm, such as ranging from 200 nm to 285 nm (e.g., 280 nm, 265 nm, or 220 nm). In certain embodiments, the light-emitting device may include a plurality of the protrusions 2100 that are separatedly disposed on the first conductive region 210 of the surface of the first type semiconductor layer 211.

In certain embodiments, the light-emitting device may further include a first electrode 701 and a second electrode 702. The first electrode 701 is disposed on the second conductive region 220 and is electrically connected to the first type semiconductor layer 211. The second electrode 702 is disposed on and electrically connected to the second type semiconductor layer 213. In certain embodiments, the light-emitting device may further include a first electrode contact layer 601 disposed between the first electrode 701 and the first type semiconductor layer 211, and a second electrode contact layer 602 disposed between the second electrode 702 and the second type semiconductor layer 213. In this embodiment, the first electrode contact layer 601 is formed on the second conductive region 220, and is covered by the first electrode 701. In certain embodiments, one of the first electrode contact layer 601 and the second electrode contact layer 602 may be made of an alloy that includes a plurality of metals, such as titanium (Ti), gold (Au), aluminum (Al), nickel (Ni), chromium (Cr), or platinum (Pt). The first electrode 701 may be made of a single metal layer. In certain embodiments, one of the first electrode 701 and the second electrode 702 may be made of one of Ti, Au, Al, Ni, Cr, and Pt.

In certain embodiments, an area of the second conductive region 220 occupies no less than 20% of an area of the surface of the first type semiconductor layer 211, and an area of a projection of the first electrode 701 on the substrate 100 occupies no less than 80% of an area of a projection of the second conductive region 220 on the substrate 100. A large contact area between the first electrode 701 and the second conductive region 220 is conducive for current spreading in the light-emitting device and avoiding current crowding.

In certain embodiments, the light-emitting device may further include a first insulating layer 400′ that partially covers the first electrode 701 and the second electrode 702, and that protects a surface of the light-emitting device.

In certain embodiments, the first reflection structure 501 may be made of a metallic material, such as rhodium, aluminum, or silver. In certain embodiments, the first reflection structure 501 may be a distributed Bragg reflection (DBR) layer, and the DBR layer may include a plurality of dielectric sublayers that have different refractive indices and that are alternately stacked , such as a titanium dioxide (TiO₂) layer, a silicon dioxide (SiO₂) layer, a hafnium oxide (HfO₂) layer, a zirconium dioxide (ZrO₂) layer, a niobium pentoxide (Nb₂O₅) layer, and a magnesium fluoride (MgF₂) layer. In this embodiment, the metallic material for forming the first reflection structure 501 is aluminum.

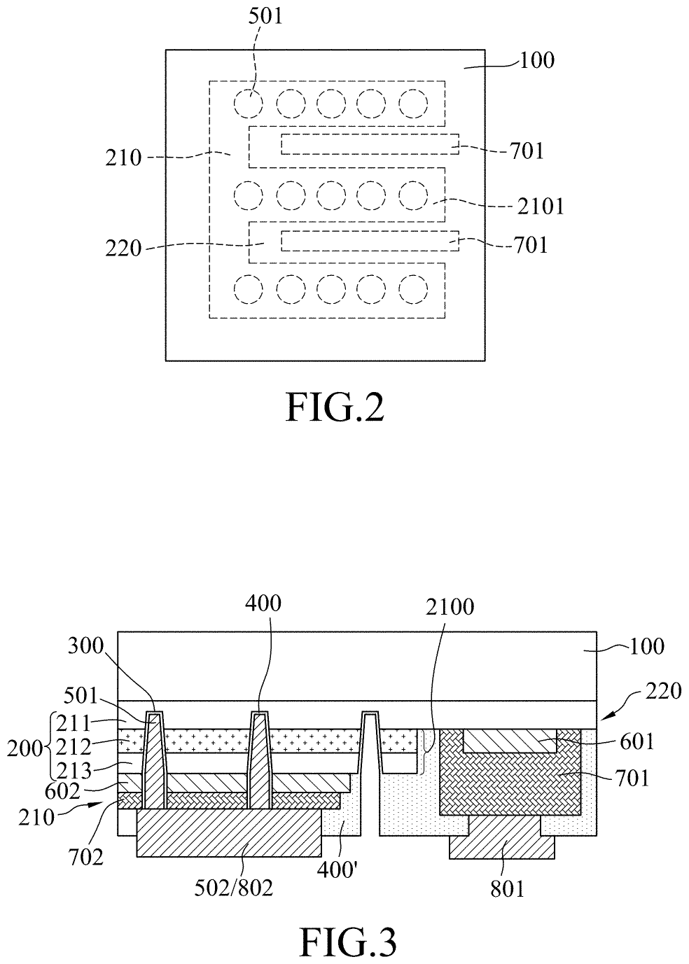

As shown in FIG. 1A, the protrusion 2100 has an extending part 2101 that extends in a first direction (i.e., X direction) parallel to the surface of the substrate 100. In this embodiment, the protrusion 2100 includes a plurality of the extending parts 2101 that are separated from one another along a second direction (i.e., Y direction) transverse to the first direction, and a connection part 2102 that extends along the Y direction to connect the extending parts 2101. In addition, the light-emitting device may include a plurality of the first reflection structures 501 that are disposed in each of the extending parts 2101 and that are separated from one another along the first direction by the second conductive region 220. With such configuration, a propagation path of light emitted from the epitaxial layer 200 in the first direction may be shortened, thereby reducing an amount of light absorbed by the first type semiconductor layer 211 of the epitaxial layer 200, and enhancing the luminous efficiency of the light-emitting device. In certain embodiments, a number of the first reflection structures 501 in each of the extending parts 2101 may not be smaller than 3 (see FIG. 1A). In a variation of this embodiment, as shown in FIG. 2, the number of the first reflection structures 501 in each of the extending parts 2101 may not be smaller than 5. In certain embodiments, the first reflection structures 501 may be equidistantly separated from one another in each of the extending parts 2101 to thereby guarantee that light emitted from the light-emitting device is uniform. In certain embodiments, in each of the extending parts 2101, the first reflection structures 501 may be equidistantly separated from one another by a spacing not greater than 110 μm, such as ranging from 20 μm to 110 μm. In certain embodiments, each of the extending parts 2101 may have a width (W) that is smaller than 110 μm in the second direction. By having the extending parts 2101 separated from one another by the second conductive region 220, each of the active layer 212 and the second type semiconductor layer 213 of the epitaxial layer 200 may have a discontinuous configuration along the second direction, so that the propagation path of light emitted from the epitaxial layer 200 along the second direction may be shortened, the amount of such light absorbed by the first type semiconductor layer 211 of the epitaxial layer 200 may be reduced, and the luminous efficiency of the light-emitting device may be enhanced. In this embodiment, the first conductive region 210 has an E-shape configuration, i.e., the extending parts 2101 and the connection part 2102 corporately form into the E-shape configuration (see FIGS. 1A and 2).

In this embodiment, the protrusion 2100 is formed with a plurality of through holes 300. Each of the through holes 300 penetrates through the second type semiconductor layer 213, the active layer 212 and into the first type semiconductor layer 211. Each of the first reflection structures 501 is a reflective pillar and is filled in a corresponding one of the through holes 300. In this embodiment, the light-emitting device further includes a plurality of second insulating layers 400. When the first reflection structures 501 are made of a metallic material, the second insulating layers 400 are also respectively disposed in each of the through holes 300 to insulate the epitaxial layer 200 and a corresponding one of the first reflection structures 501. In certain embodiments, the through holes 300 are respectively defined by a plurality of hole-defining walls, and each of the first reflection structures 501 is a reflection layer and is formed on a corresponding one of the hole-defining walls. In such case, when the first reflection structures 501 are made of a metallic material, each of the second insulation layers 400 is disposed between a corresponding one of the hole-defining walls and a corresponding one of the first reflection structures 501.

In this embodiment, the light-emitting device may further include a second reflection structure 502 that covers a surface of the second type semiconductor layer 213 on the first conductive region 210, and that reflects light emitted from the epitaxial layer 200 to a light exiting surface of the light-emitting device in a direction from the second type semiconductor layer 213 to the first type semiconductor layer 211, thereby increasing the amount of light passing through the light exiting surface of the light-emitting device. In certain embodiments, the second reflection structure 502 may be integrally formed with at least one of the first reflection structures 501. In alternative embodiments, the second reflection structure 502 may be separated from a corresponding one of the first reflection structures 501 by a corresponding one of the second insulating layers 400. In certain embodiments, the second reflection structure 502 is made of a metallic material, and may serve as an electrode or an electrode pad. In this embodiment, the second reflection structure 502 is integrally formed with at least two of the first reflection structures 501, and serves as the second electrode 702 (see FIG. 1B).

A ratio of an area of a projection of the first reflection structures 501 on the substrate 100 to an area of a projection of the epitaxial layer 200 (in particular, the active layer 212) on the substrate 100 may significantly affect the amount of light emitted from the light-emitting device. In this embodiment, the area of the projection of the first reflection structures 501 on the substrate 100 occupies no less than 30% (e.g., ranging from 40% to 60%) of the area of the projection of the active layer 212 on the substrate 100. In certain embodiments, an area of a projection of each of the first reflection structures 501 on the substrate 100 occupies no more than 10% (e.g., ranging from 2% to 8%) of the area of the projection of the active layer 212 on the substrate 100. By controlling the ratio of the area of the first reflection structures 501 with respect to the area of the active layer 212, the luminous efficiency of the light-emitting device may be efficiently enhanced, and impact on the amount of light emitted from the light-emitting device caused by a light-emitting area of the light-emitting device occupied by the first reflection structures 501 may be reduced.

In this embodiment, the light-emitting device may further include a first electrode pad 801 and a second electrode pad 802. The first electrode pad 801 is disposed on the first electrode 701. The second electrode pad 802 is disposed on the second electrode 702. Each of the first electrode pad 801 and the second electrode pad 802 is made of a metallic material.

Referring to FIG. 3, a second embodiment of the light-emitting device according to the present disclosure is generally similar to the first embodiment, except that, in the second embodiment, the second electrode pad 802 serves as the second reflection structure 502 to reflect light emitted from the epitaxial layer 200. In this embodiment, the second electrode pad 802 is made of a reflective metal, such as aluminum or silver. In such case, the second electrode pad 802 may be integrally formed with the at least two of the first reflection structures 501 (i.e., the at least two of the first reflection structures 501 extend through the second electrode 702). It is noted that the through hole 300 that is located proximate to the second conductive region 220 is not filled by the first reflection structure 501 to thereby prevent the second electrode pad 802 from being in electrical contact with the first electrode pad 801.

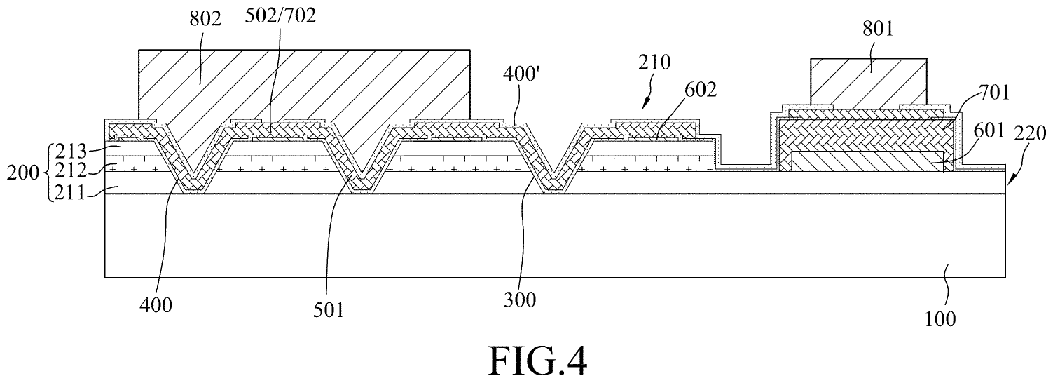

Referring to FIG. 4, a third embodiment of the light-emitting device according to the present disclosure is generally similar to the first embodiment, except for the follow differences. The first reflection structures 501 and the second reflection structures 502 cooperate to form as a continuous layer, and such continuous layer covers the epitaxial layer 200.

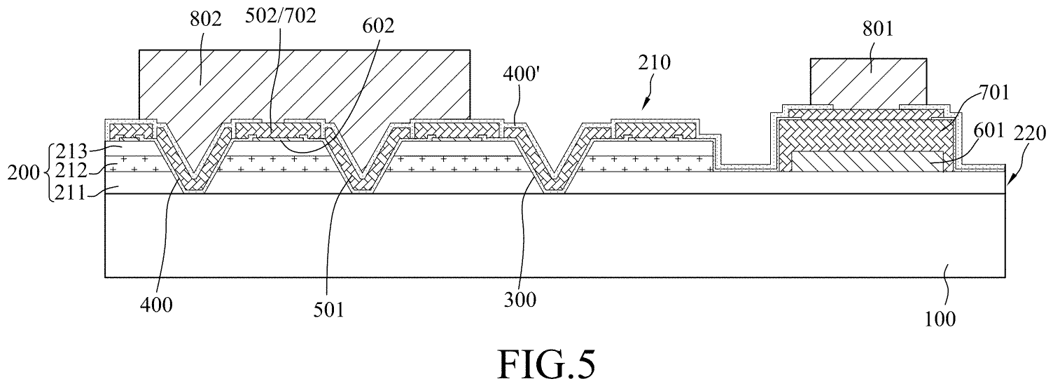

Referring to FIG. 5, in a variation of the third embodiment, each of the second reflection structures 502 is separated from a corresponding one of the first reflection structures 501 by the first insulating layer 400′. In such case, each of the second reflection structures 502 may serve as the second electrode 702.

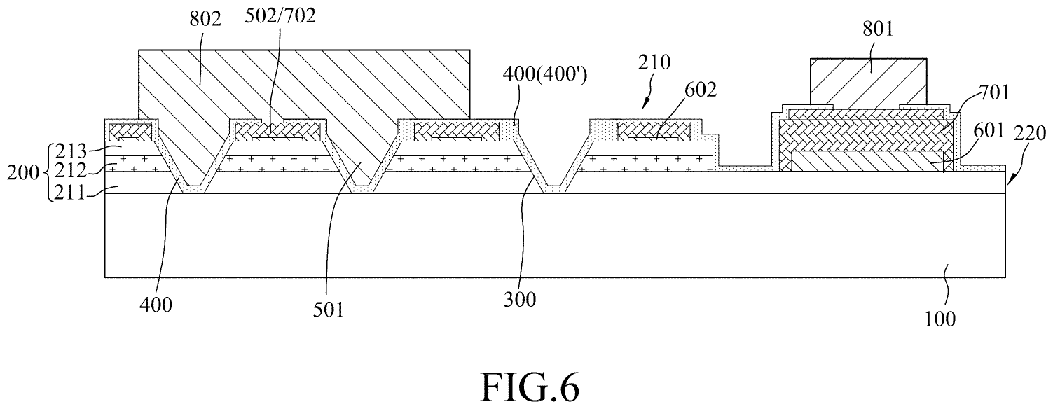

Referring to FIG. 6, in yet another variation of the third embodiment, the first reflection structures 501 serve as the second electrode pad 802, and the first insulating layer 400′ (see FIG. 4) is integrally formed with the second insulating layers 400.

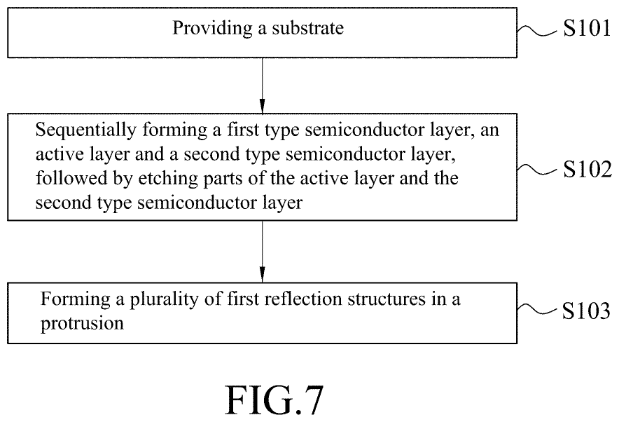

Referring to FIG. 7, this disclosure provides a method for making the first embodiment of the light-emitting device according to the present disclosure, which includes the following consecutive steps from S101 to S103.

In step S101, the substrate 100 is provided.

In step S102, the first type semiconductor layer 211, the active layer 212, and the second type semiconductor layer 213 are sequentially formed on the substrate 100, followed by etching parts of the active layer 212 and the second type semiconductor layer 213 to expose a part of the first type semiconductor layer 211. The surface of the exposed part of the first type semiconductor layer 211 serves as the second conductive region 220, and a remaining part of the first type semiconductor layer 211 serves as the first conductive region 210. The protrusion 2100 that includes the active layer 212 and the second type semiconductor layer 213 that are subjected to the etching procedure is disposed on the first conductive region 210.

In certain embodiments, the first type semiconductor layer 211, the active layer 212, and the second type semiconductor layer 213 are formed by chemical vapor deposition. Details of the first type semiconductor layer 211, the active layer 212, the second type semiconductor layer 213, the first conductive region 210, the second conductive region 220, and the protrusion 2100 are described above, and therefore are omitted herein for the sake of brevity.

In step S103, the first reflection structures 501 are formed in the protrusion 2100.

As shown in FIGS. 1B, 4, and 5, in certain embodiments, step S103 may include the following sub-steps: (i) depositing the second electrode contact layer 602 on the surface of the second type semiconductor layer 213; (ii) sequentially etching the second type semiconductor layer 213, the active layer 212 and the first type semiconductor layer 211 to form the through holes 300; (iii) depositing an insulating material layer in the respective one of the hole-defining walls to form the second insulating layers 400; and (iv) depositing a metallic material layer on the second insulating layers 400, so as to form the reflection layers (see FIGS. 4 and 5) or the reflective pillars (see FIG. 1). In certain embodiments, after formation of the reflection layers or the reflective pillars, the second electrode 702 is formed on the second electrode contact layer 602 opposite to the substrate 100. When the second electrode 702 is made of a metallic material, the second electrode 702 may serve as the second reflection structure 502 to reflect light emitted from the epitaxial layer 200. In such case, the at least two of the first reflection structures 501 may be integrally formed with the second electrode 702. In certain embodiments, after formation of the second electrode 702, the first electrode contact layer 601 is formed on the exposed part of the first type semiconductor layer 211, and then the first electrode 701 is formed on the first electrode contact layer 601.

In certain embodiments, after formation of the first electrode 701, the first insulating layer 400′ is formed on the first electrode 701, the second electrode 702 and the protrusion 2100, and is then subjected to an etching process to expose parts of the first electrode 701 and the second electrode 702. After that, the first electrode pad 801 and the second electrode pad 802 may be formed on the exposed parts of the first electrode 701 and the second electrode 702, respectively.

In certain embodiments, as shown in FIG. 3 or 6, step S103 may include the following sub-steps: (i) sequentially forming the second electrode contact layer 602 and the second electrode 702 on the surface of the second type semiconductor layer 213; (ii) conducting an etching process to form the through holes 300 that penetrate through the second electrode 702, the second electrode contact layer 602, the second type semiconductor layer 213, the active layer 212, and at least a part of the first type semiconductor layer 211; (iii) forming the second insulating layers 400 on the hole-defining walls that respectively define the through holes 300, and a surface of the second electrode 702; (iv) etching away a part of a corresponding one of the second insulating layers 400 to expose a part of the surface of the second electrode 702; and (v) depositing a metallic material layer in the through holes 300 and on the exposed part of the second electrode 702, so as to form the first reflection structures 501 and the second electrode pad 802.

In sum, with dispositions of the extending parts 2101 and the first reflection structures 501, the amount of light (i.e., emitted from the active layer 212) being absorbed by the first type semiconductor layer 211 may effectively be reduced, which is conducive for shortening the propagation path of light (in the first and second directions) and enhancing the luminous efficiency of the light-emitting device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate;
a first type semiconductor layer disposed on a surface of said substrate, and having a surface that has a first conductive region and a second conductive region, said first type semiconductor layer being made of x ranging from 0 to 1;
a protrusion including an active layer and a second type semiconductor layer that are sequentially disposed on said first conductive region of said surface of said first type semiconductor layer in such order; and
a first reflection structure disposed in said protrusion, and penetrating through said second type semiconductor layer, said active layer of said protrusion and into said first type semiconductor layer,
wherein said light-emitting device emits light that has an emission wavelength ranging from 200 nm to 320 nm.

2. The light-emitting device as claimed in claim 1, wherein said x ranges from 0.5 to 0.8.

3. The light-emitting device as claimed in claim 1, wherein said protrusion has an extending part that extends in a first direction parallel to said surface of said substrate.

4. The light-emitting device as claimed in claim 3, wherein said light-emitting device includes a plurality of said first reflection structures that are disposed in said extending part and that are separated from one another along said first direction.

5. The light-emitting device as claimed in claim 4, wherein said first reflection structures are equidistantly separated from one another in said extending part.

6. The light-emitting device as claimed in claim 5, wherein said first reflection structures are equidistantly separated from one another by a spacing smaller than 110 μm.

7. The light-emitting device as claimed in claim 1, wherein said light-emitting device includes a plurality of said first reflection structures disposed in said protrusion, an area of a projection of said first reflection structures on said substrate occupying no less than 30% of an area of a projection of said active layer on said substrate.

8. The light-emitting device as claimed in claim 1, wherein said light-emitting device includes a plurality of said first reflection structures disposed in said protrusion, an area of a projection of said first reflection structures on said substrate occupying between 40% to 60% of an area of a projection of said active layer on said substrate.

9. The light-emitting device as claimed in claim 1, wherein said light-emitting device includes a plurality of said first reflection structures, said protrusion being formed with a plurality of through holes, each of said through holes penetrating through said second type semiconductor layer, said active layer and into said first type semiconductor layer, each of said first reflection structures being a reflective pillar and being filled in a corresponding one of said through holes.

10. The light-emitting device as claimed in claim 1, wherein said light-emitting device includes a plurality of said first reflection structures, said protrusion being formed with a plurality of through holes that are respectively defined by a plurality of hole-defining walls, each of said through holes penetrating through said second type semiconductor layer, said active layer, into said first type semiconductor layer, each of said first reflection structures being a reflection layer and being formed on a corresponding one of said hole-defining walls.

11. The light-emitting device as claimed in claim 10, wherein said reflection layer is a distributed Bragg reflection layer.

12. The light-emitting device as claimed in claim 10, further comprising a plurality of insulation layers respectively disposed between a corresponding one of said hole-defining walls and a corresponding one of said first reflection structures.

13. The light-emitting device as claimed in claim 1, wherein said first reflection structure is made of a metallic material selected from the group consisting of rhodium, aluminum, silver, and combinations thereof.

14. The light-emitting device as claimed in claim 1, further comprising a second reflection structure that covers a surface of said second type semiconductor layer on said first conductive region.

15. The light-emitting device as claimed in claim 14, wherein said second reflection structure serves as an electrode to electrically connect to said second type semiconductor layer.

16. The light-emitting device as claimed in claim 14, wherein said second reflection structure serves as an electrode pad to electrically connect to said second type semiconductor layer.

17. The light-emitting device as claimed in claim 1, further comprising a first electrode disposed on and being electrically connected to said second conductive region.

18. The light-emitting device as claimed in claim 17, wherein an area of said second conductive region occupies no less than 20% of an area of said surface of said first type semiconductor layer, and an area of a projection of said first electrode on said substrate occupies no less than 80% of an area of a projection of said second conductive region on said substrate.

19. The light-emitting device as claimed in claim 1, wherein said light-emitting device emits light that has an emission wavelength ranging from 200 nm to 285 nm.

20. The light-emitting device as claimed in claim 4, wherein said extending part has a width (W) that is smaller than 110 μm in a second direction transverse to said first direction.
